(19) United States
(12) Patent Application Publication
(10) Pub. No.: US 2021/0313244 A1
(43) Pub. Date: Oct. 7, 2021

(54) FINGERPRINT IDENTIFICATION CHIP PACKAGE AND METHOD FOR MAKING SAME

(71) Applicant: SOCLE TECHNOLOGY CORP., Hsinchu (TW)

(72) Inventors: HSIANG-HUA LU, New Taipei (TW); YING-CHIEH PAN, New Taipei (TW); CHING-YU NI, New Taipei (TW)

(21) Appl. No.: 17/002,069

(22) Filed: Aug. 25, 2020

(30) Foreign Application Priority Data
Apr. 2, 2020 (CN) 202010253921.4

(51) Int. Cl. H01L 23/31; H01L 23/00; H01L 21/56; G06K 9/00

(52) U.S. Cl. CPC H01L 23/3128; H01L 2224/83191; H01L 24/83; H01L 24/32; H01L 24/24; H01L 24/96; H01L 21/561; G06K 9/0002; H01L 23/562; H01L 2224/29023; H01L 2224/2919; H01L 2224/831; H01L 2224/32225; H01L 2224/24175; H01L 24/29

(57) ABSTRACT

A fingerprint identification chip package of reduced thickness in not requiring a supporting substrate includes a packaging material layer, a fingerprint identification chip in the packaging material layer, conductive pillars in the packaging material layer for structural support, the pillars being spaced apart from the fingerprint identification chip, and a redistribution layer on a side of the packaging material layer. The redistribution layer includes connecting wires, each wire is electrically coupled between the fingerprint identification chip and one conductive pillar. A plurality of pins is on a side of the packaging material layer opposite to the redistribution layer, each pin is electrically coupled to one conductive pillar.

### FIELD

The subject matter herein generally relates to a field of semiconductor packaging, particularly relates to a fingerprint identification chip package and a method for making the fingerprint identification chip package.

### BACKGROUND

Fingerprint identification technology is used in electronic devices such as display devices, attendance equipment, door locks, and so on. Since the fingerprint identification chip has a small thickness and is easily broken or damaged during the packaging process, the fingerprint identification chip is usually packaged on a substrate. The substrate may be a printed circuit board, and the fingerprint identification chip is electrically connected to the substrate. That is, the fingerprint recognition chip is packaged with the printed circuit board. Then the fingerprint identification chip packaged with the substrate is connected to a motherboard (such as a TFT substrate of a liquid crystal display device). However, the substrate makes the overall package thickness of the fingerprint identification chip thicker, which is not conducive to a thinner electronic device using the fingerprint identification chip. Therefore, there is room for improvement in the art.

### BRIEF DESCRIPTION OF THE DRAWINGS

Implementations of the present technology will now be described, by way of embodiments only, with reference to the attached figures.

FIG. 1 is a cross-sectional view of a fingerprint identification chip package.

FIG. 2 is a cross-sectional view showing step S1 in manufacturing the fingerprint identification chip package.

FIG. 3 is a cross-sectional view showing step S2 in manufacturing the fingerprint identification chip package.

FIG. 4 is a cross-sectional view showing step S3 in manufacturing the fingerprint identification chip package.

FIG. 5 is a cross-sectional view showing step S4 in manufacturing the fingerprint identification chip package.

FIG. 6 is a cross-sectional view showing step S5 in manufacturing the fingerprint identification chip package.

FIG. 7 is a cross-sectional view showing step S6 in manufacturing the fingerprint identification chip package.

FIG. 8 is a cross-sectional view showing step S7 in manufacturing the fingerprint identification chip package.

FIG. 9 is a cross-sectional view showing step S8 in manufacturing the fingerprint identification chip package.

FIG. 10 is a cross-sectional view showing step S9 in manufacturing the fingerprint identification chip package.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The redistribution layer is a component in a semiconductor packaging, and can be used in a semiconductor packaging (especially a fan-out panel-level packaging) to electrically connect a chip to a circuit board.

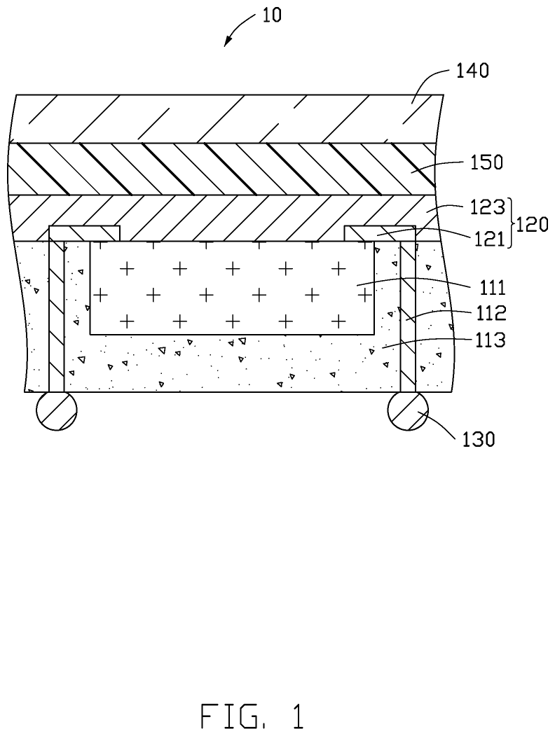

FIG. 1 shows a fingerprint identification chip package 10. The fingerprint identification chip package 10 includes a fingerprint identification chip 111, a plurality of conductive pillars 112, and a packaging material layer 113 covering the fingerprint identification chip 111 and the conductive pillars 112. FIG. 1 shows only two conductive pillars 112. The fingerprint identification chip 111 is embedded in the packaging material layer 113 and a surface of the fingerprint identification chip 111 is exposed from the packaging material layer 113. Each conductive pillar 112 is also embedded in the packaging material layer 113 and spaced apart from the fingerprint identification chip 111. Each conductive pillar 112 extends through the packaging material layer 113 in a thickness direction of the packaging material layer 113 and has opposite ends that are exposed from the packaging material layer 113. Each conductive pillar 112 is electrically connected to the fingerprint identification chip 111.

The fingerprint identification chip 111 may be, for example, an optical fingerprint identification chip, a capacitive fingerprint identification chip, or an ultrasonic fingerprint identification chip. The conductive pillar 112 may be made of a metal or alloy having good conductivity, such as copper or copper alloy. The encapsulating material layer 113 may be made of a material selected from at least one of polyimide, silicone, and epoxy resin, but it is not limited thereto.

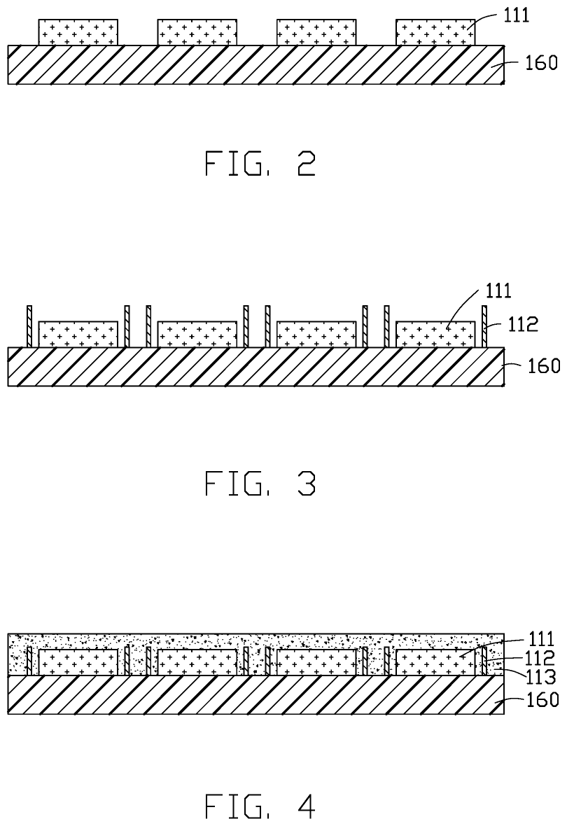

The fingerprint identification chip package 10 further includes a redistribution layer 120. The redistribution layer 120 is positioned on the packaging material layer 113 and completely covers the surface of the fingerprint identification chip 111 exposed from the packaging material layer 113. The redistribution layer 120 includes a plurality of wires 121. FIG. 2 shows two wires 121. The fingerprint identification chip 111 is electrically connected to each conductive pillar 112 by one of the wires 121. Each wire 121 is electrically coupled between the fingerprint identification chip 111 and one of the conductive pillars 112. The wire 121 is made of a metal or an alloy having good electrical conductivity, for example, it may be at least one of copper, aluminum, nickel, gold, silver, and titanium. In one embodiment, the conductive pillar 112 may be made of the same material as the wire 121.

The redistribution layer 120 further includes insulating material 123 that is infilled between the wires 121 so that the wires 121 are insulated from each other. The insulating material 123 may be, for example, epoxy resin, silicone, polyimide (PI), or polyparaphenylenebenzo bisoxazole (PBO), benzocyclobutene (BCB), silicon oxide or phosphosilicate glass. The insulating material 123 completely covers the wires 121, which protects the wires 121 from being damaged and does not affect signal transmission of each wire 121. In the present embodiment, the fingerprint identification chip package 10 includes only one fingerprint identification chip 111. In other embodiments, the fingerprint identification chip package 10 may include two or more fingerprint identification chips 111, and a number of the fingerprint identification chips 111 may be designed according to actual requirement.

The fingerprint identification chip package 10 further includes a plurality of pins 130. The pins 130 are positioned on a side of the packaging material layer 113 away from the redistribution layer 120. The pins 130 and the conductive pillars 112 are in a one-to-one relationship, and each pin 130 is coupled to one of the conductive pillars 112. The wires 121, the conductive pillars 112, and the pins 130 cooperate with each other to electrically connect the fingerprint identification chip 111 to an external circuit (not shown). The external circuit is used to drive the fingerprint identification chip 111 to work, such as power supply for the fingerprint identification chip 111, and the external circuit may also receive the fingerprint identification signals from the fingerprint identification chip 111. The pins 130 are made of a metal or an alloy, such as at least one of wire, tin, and silver, or an alloy including wire, tin, or silver, but not limited thereto. In this embodiment, the pin 130 has a spherical shape.

The fingerprint identification chip package 10 further includes a protective layer 140. The protective layer 140 is positioned on a side of the redistribution layer 120 away from the packaging material layer 113, and is configured to protect the redistribution layer 120. The protective layer 140 is scratch-resistant. The protective layer 140 may be made of material with a high dielectric constant, such as at least one of sapphire, glass, ceramic, quartz, acrylic, and plastic, but it is not limited thereto.

A bonding film 150 is provided between the protective layer 140 and the redistribution layer 120. The bonding film 150 is configured to bond the protective layer 140 and the redistribution layer 120 together. The material of the bonding film 150 may be a translucent adhesive not easily oxidized, such as a B-stage (B-stage) polymer adhesive or a FOW (film-over-wire) film.

The fingerprint identification chip package 10 does not need a substrate, so reduces an overall packaging thickness of the fingerprint identification chip package 10. Specifically, the overall packaging thickness of the fingerprint identification chip package 10 can be reduced to less than 1 mm.

A method for making the above fingerprint identification chip package 10 is also provided in the present disclosure. FIG. 2 through FIG. 10 are cross-sectional views showing each step of method for making the fingerprint identification chip package 10. The method for making the fingerprint identification chip package 10 includes the following steps.

The example method is provided by way of example, as there are a variety of ways to carry out the method. The method described below can be carried out using the configurations illustrated in FIG. 2 through FIG. 10, for example, and various elements of these figures are referenced in explaining example method. Each step described represents one or more processes, methods or subroutines, carried out in the exemplary method. Additionally, the illustrated order of steps is by example only and the order of the steps can change according to the present disclosure. The exemplary method can begin at step S1.

Step S1: a carrier plate 160 is provided and a plurality of fingerprint identification chips 111 are formed on the carrier plate 160 at intervals, wherein a front side of each fingerprint identification chip 111 faces the carrier plate 160, as shown in FIG. 2. The carrier plate 160 may be a plastic or glass plate. Each fingerprint identification chip 111 is in direct contact with the carrier plate 160.

Step S2: conductive pillars 112 are formed on the carrier plate 160, as shown in FIG. 3. Each conductive pillar 112 is spaced part from each fingerprint identification chip 111. In this embodiment, at least two conductive pillars 112 correspond to and surround each fingerprint identification chip 111.

In this embodiment, a height of the conductive pillar 112 is greater than a height of the fingerprint identification chip 111 in a thickness direction of the carrier plate 160. An end of the conductive pillar 112 away from the carrier plate 160 extends beyond an end surface of the fingerprint identification chip 111 away from the carrier plate 160. Specifically, the conductive pillar 112 may be formed by forming a columnar conductive material (for example a copper pillar) on the carrier plate 160, or may be formed by forming a metal layer on the carrier plate 160 and then patterning the metal layer to form a plurality of metal pillars.

Step S3: a packaging material layer 113 is formed on the carrier plate 160, so that the packaging material layer 113 encapsulates and embeds the fingerprint identification chip 111 and the conductive pillars 112, as shown in FIG. 4.

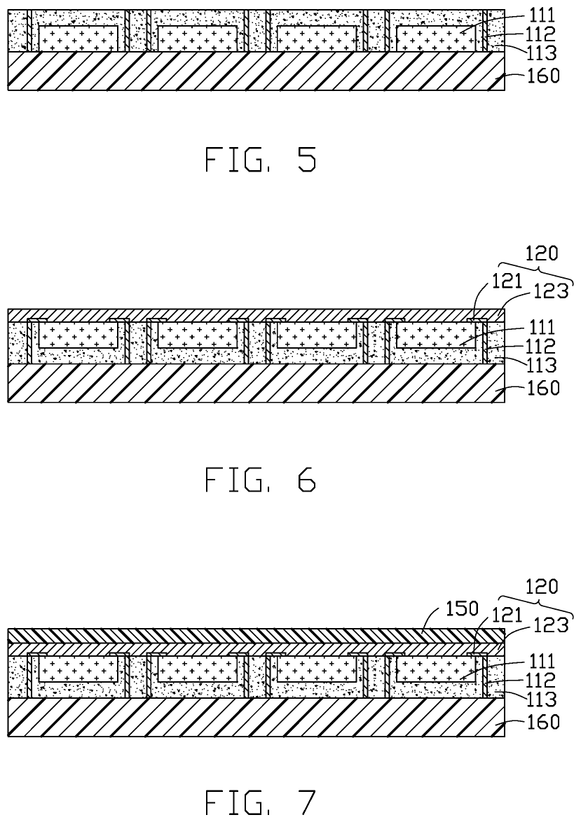

Step S4: a surface of the packaging material layer 113 away from the carrier plate 160 is ground so that the surface of the packaging material layer 113 away from the carrier plate 160 is flush with the end surface of the conductive pillar 112 away from the carrier plate 160, as shown in FIG. 5.

Step S5: As shown in FIG. 6, the carrier plate 160 is transferred from a side of the packaging material layer 113 to an opposite side of the packaging material layer 113. That is, the carrier plate 160 is transferred to a ground surface of the packaging material layer 113 and is not in direct contact with the fingerprint identification chip 111. Then a redistribution layer 120 is formed on a surface of the packaging material layer 113 away from the carrier plate 160. The redistribution layer 120 includes a plurality of wires 121 and insulating material 123 infilling between the wires 121. The wires 121 are electrically coupled between the fingerprint identification chip 111 and the conductive pillar 112, as shown in FIG. 6.

Step S6: a bonding film 150 is attached on a side of the redistribution layer 120 away from the packaging material layer 113, as shown in FIG. 7. The bonding film 150 has opposite adhesive surfaces, a surface of the redistribution layer 120 away from the packaging material layer 113 is attached to one of the opposite adhesive surfaces.

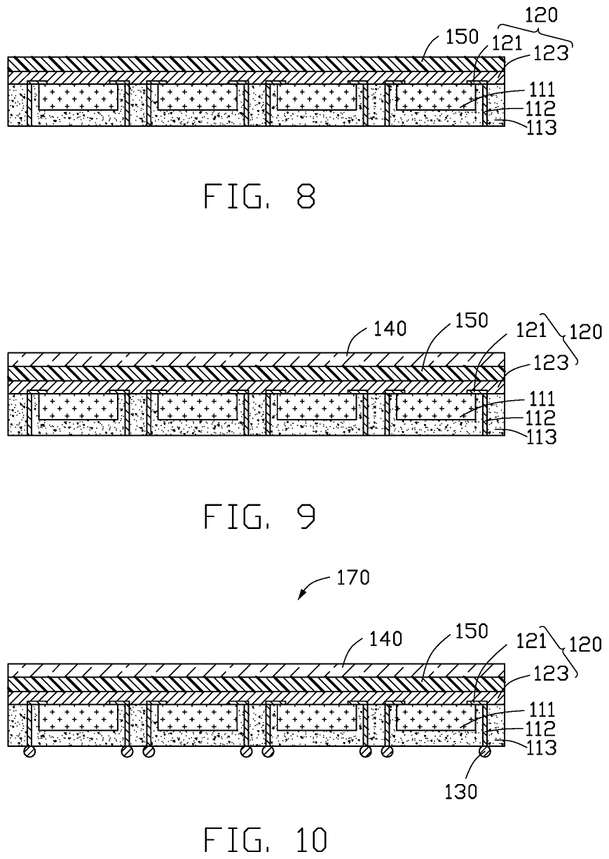

Step S7: the carrier plate 160 is removed, as shown in FIG. 8. The carrier plate 160 is peeled off from the packaging material layer 113.

Step S8: a protective layer 140 is attached to a surface of the bonding film 150 away from the redistribution layer 120, as shown in FIG. 9. The protective film 140 is attached to the other one of the opposite adhesive surfaces of the bonding film 150.

Step S9: a plurality of pins 130 is formed on a surface of the packaging material layer 113 away from the redistribution layer 120, and each pin 130 is electrically connected to one of the conductive pillars 112. After this step, a fingerprint identification chip package array 170 is obtained as shown in FIG. 10.

Step S10: the fingerprint identification chip package array 170 is cut to obtain a plurality of fingerprint identification chip packages 10 independent from each other. Each fingerprint identification chip package 10 may include one fingerprint identification chip 111 as shown in FIG. 1.

After cutting, the number of fingerprint identification chips 111 in each fingerprint identification chip package 10 can be adjusted according to actual needs.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A fingerprint identification chip package, comprising:
a packaging material layer;
a fingerprint identification chip in the packaging material layer;
a plurality of conductive pillars in the packaging material layer and spaced apart from the fingerprint identification chip;
a redistribution layer on a side of the packaging material layer, the redistribution layer comprising a plurality of wires, each of the plurality of wires electrically coupled between the fingerprint identification chip and one of the plurality of conductive pillars; and
a plurality of pins on a side of the packaging material layer opposite to the redistribution layer, each of the plurality of pins electrically coupled to one of the plurality of conductive pillars.

2. The fingerprint identification chip package of claim 1, wherein the fingerprint identification chip is embedded in the packaging material layer and comprises a surface exposed from the packaging material layer.

3. The fingerprint identification chip package of claim 1, wherein each of the plurality of conductive pillars extends through the packaging material layer in a thickness direction of the packaging material layer.

4. The fingerprint identification chip package of claim 3, wherein each of the plurality of conductive pillars comprises opposite ends that are exposed from the packaging material layer.

5. The fingerprint identification chip package of claim 1, wherein the redistribution layer further comprises insulating material filling between the plurality of wires so that the plurality of wires are insulated from each other.

6. The fingerprint identification chip package of claim 1, wherein the encapsulating material layer is made of a material selected from at least one of polyimide, silicone, and epoxy resin.

7. The fingerprint identification chip package of claim 1, wherein the fingerprint identification chip is an optical fingerprint identification chip, a capacitive fingerprint identification chip, or an ultrasonic fingerprint identification chip.

8. The fingerprint identification chip package of claim 1, further comprising a protective layer, wherein the protective layer is positioned on a side of the redistribution layer away from the packaging material layer.

9. The fingerprint identification chip package of claim 8, wherein the protective layer is made of sapphire, glass, ceramic, quartz, acrylic, or plastic.

10. The fingerprint identification chip package of claim 8, wherein a bonding film is provided between the protective layer and the redistribution layer; the bonding film is configured to bond the protective layer and the redistribution layer together.

11. A method for making a fingerprint identification chip package, comprising:
providing a carrier plate and forming a plurality of fingerprint identification chips on a surface of the carrier plate at intervals;
forming a plurality of conductive pillars on the surface of the carrier plate and spaced apart from each of the plurality of fingerprint identification chips;
forming a packaging material layer on the carrier plate to encapsulate the plurality of fingerprint identification chips and the plurality of conductive pillars;
grinding a surface of the packaging material layer away from the carrier plate to make the packaging material layer to flush with the each of the plurality of conductive pillars;
transferring the carrier plate to a grinded surface of the packaging material layer and forming a redistribution layer on a surface of the packaging material layer away from the carrier plate, the redistribution layer comprising a plurality of wires each electrically coupled between one of the plurality of fingerprint identification chips and one of the plurality of conductive pillars;
removing the carrier plate; and
forming a plurality of pins on a surface of the packaging material layer away from the redistribution layer, and each of the plurality of pins electrically connected to one of the plurality of conductive pillars.

12. The method of claim 11, wherein forming the plurality of conductive pillars comprises forming at least two conductive pillars corresponding to and surrounding each of the plurality of fingerprint identification chips.

13. The method of claim 11, wherein forming the plurality of conductive pillars comprises forming each of plurality of conductive pillars having a height greater than a height of the fingerprint identification chip in a thickness direction of the carrier plate.

14. The method of claim 11, wherein forming the encapsulating material layer comprises forming the encapsulating material layer made of a material selected from at least one of polyimide, silicone, and epoxy resin.

15. The method of claim 11, further comprising forming a bonding film on a side of the redistribution layer away from the packaging material layer after transferring the carrier plate.

16. The method of claim 15, further comprising forming a protective layer on a surface of the bonding film away from the redistribution layer.

17. The method of claim 11, wherein a fingerprint identification chip package array is formed after forming the plurality of pins; and the method further comprises cutting the fingerprint identification chip package array to obtain a plurality of fingerprint identification chip packages independent from each other, each of the plurality of fingerprint identification chip packages comprises at least one fingerprint identification chip.
